(19) United States
(12) Patent Application Publication
(10) Pub. No.: US 2023/0155204 A1
(43) Pub. Date: May 18, 2023

(54) ELECTRONIC DEVICE COMPRISING A BATTERY AND A PROTECTION MODULE

(71) Applicant: ETA SA Manufacture Horlogère Suisse, Grenchen (CH)

(72) Inventor: Stéphane BALEON, La Neuveville (CH)

(73) Assignee: ETA SA Manufacture Horlogère Suisse, Grenchen (CH)

(21) Appl. No.: 18/049,455

(22) Filed: Oct. 25, 2022

(30) Foreign Application Priority Data
Nov. 16, 2021 (WO) 21208584.9

(51) Int. Cl. H01M 10/613; G06F 1/16; H01M 10/6595; H01M 10/42

(52) U.S. Cl. CPC H01M 10/613; G06F 1/1635; G06F 1/163; H01M 10/6595; H01M 10/4235

(57) ABSTRACT

An electronic device, in particular an electronic watch, including a case and an electronic system arranged within the case, the case being provided with a housing for a battery allowing supplying the electronic system with energy, wherein it includes a standalone endothermic protection module configured to be automatically triggered in the event of thermal runaway of the battery in order to absorb heat.

### TECHNICAL FIELD OF THE INVENTION

The invention relates to the field of electronic devices provided with batteries.

### TECHNOLOGICAL BACKGROUND

Batteries of electronic devices, such as watches or mobile phones, might undergo a thermal runaway in a non-predictable manner, for example following an impact, extreme temperatures, and even production defects. Despite a high-quality production, it is common to always estimate a risk of one to ten for one million of undergoing a thermal runaway over the service life of a battery. Despite the use of batteries originating from productions having high standards on quality control, some manufacturers of electronic devices are often sued by users having had a wrist burnt by a defective product.

In this thermal runaway situation, all of the chemical energy of the battery is released in a few seconds in the form of thermal energy. For example, a Lithium Ion CR2032 battery of 100 mAh could rise to more than 100° C. in less than one minute.

When the electronic device is in contact with the skin, for example for watch products, the temperature of the case might increase beyond the burning threshold and hurt the wearer of the watch.

### SUMMARY OF THE INVENTION

The invention is intended to overcome the aforementioned drawbacks, and aims to provide an electronic device provided with a battery, which protects the wearer of the electronic device from the risk of burn in the event of thermal runaway of the battery.

To this end, the invention relates to an electronic device, in particular an electronic watch, comprising a case and an electronic system arranged within the case, the case being provided with a housing for a battery allowing supplying the electronic system with energy.

The electronic device is remarkable in that it comprises a standalone endothermic protection module configured to be automatically triggered in the event of thermal runaway of the battery in order to absorb heat.

As regards the cases where a battery malfunctions while heating up very intensely, the protection module is triggered and absorbs at least part of the heat produced by the battery. Thus, the user of the electronic device is protected against the risk of burn.

Thanks to the invention, resort to thermal protections that are complex to implement, with regards to the inner arrangement within the electronic device, is avoided. In addition, the module could be adapted on existing electronic devices.

According to a particular embodiment of the invention, the module is automatically triggered starting from a threshold temperature.

According to a particular embodiment of the invention, the thermal protection module comprises two products that are separate before triggering, and which mix together after the automatic triggering.

According to a particular embodiment of the invention, the two products are separated by a wall before triggering, the wall being degradable beyond a threshold temperature.

According to a particular embodiment of the invention, the wall comprises a metal alloy with a low melting point.

According to a particular embodiment of the invention, the two products are arranged within an enclosure disposed in the housing.

According to a particular embodiment of the invention, the enclosure includes a plurality of compartments, each compartment including one of the two products.

According to a particular embodiment of the invention, the compartments alternatively comprise each product.

According to a particular embodiment of the invention, the compartments are closed by a wall that is degradable beyond the threshold temperature.

According to a particular embodiment of the invention, the first and second products to be mixed are selected from among the following pairs:
ammonium nitrate and water,
potassium chloride and water,
sodium carbonate and ethanoic acid,
thionyl chloride and cobalt sulphate heptahydrate,
Barium hydroxide octohydrate crystals and dry ammonium chloride.

According to a particular embodiment of the invention, the wall comprises, preferably in its entirety, a material to be selected from the following list: an indium-Titanium nitride eutectic alloy, a Rose metal type Lead-Bismuth-tin alloy, a Lead-Bismuth alloy, a Bismuth-Titanium nitride eutectic alloy, a Bismuth-Indium eutectic alloy.

According to a particular embodiment of the invention, the wall comprises, preferably in its entirety, a polymer material, for example ABS-type acrylonitrile butadiene styrene, LDPE-type low-density polyethylene, or PVC-type polyvinyl chloride

According to a particular embodiment of the invention, the endothermic protection module is arranged within the case.

According to a particular embodiment of the invention, the endothermic protection module is arranged outside the case.

According to a particular embodiment of the invention, the wall comprises, preferably in its entirety, a metal alloy with a low melting point

### BRIEF DESCRIPTION OF THE FIGURES

The aims, advantages and features will appear upon reading the following detailed description, with reference to the appended drawings, where:

FIG. 1 shows a schematic representation of a first embodiment of an electronic watch provided with a battery, and with a thermal protection module according to the invention,

FIG. 2 shows a schematic representation of a first embodiment of a thermal protection module before triggering,

FIG. 3 shows a schematic representation of the first embodiment of the thermal protection module after triggering, and

FIG. 4 shows a schematic representation of a second embodiment of a thermal protection module.

### DETAILED DESCRIPTION OF THE INVENTION

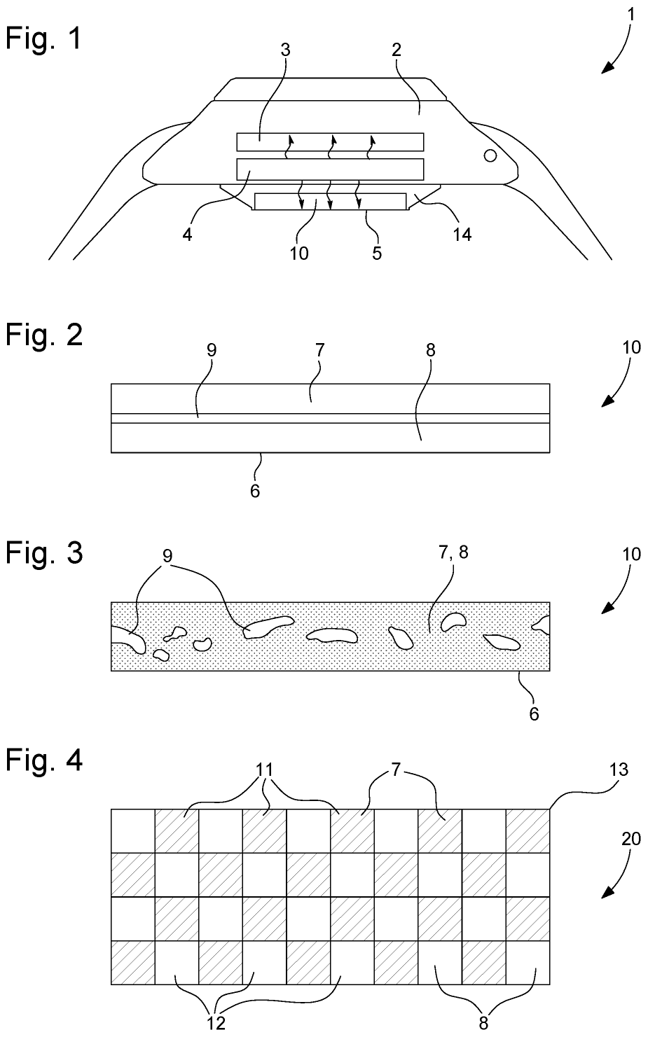

FIG. 1 represents an electronic device 1, herein a watch, comprising a case 2, within which an electronic system 3 is arranged. For example, the electronic system 3 comprises an electronic quartz motor, and digital or analogue hand-type display means which are controlled by the electronic motor. The case 2 of the watch comprises a housing 14 for a battery 4 allowing powering the electronic system 3.

According to the invention, the watch comprises an endothermic protection module 10 configured to be triggered in the event of thermal runaway of the battery 4 in order to absorb heat.

In the example of FIG. 1, the protection module 10 is arranged within the housing between the battery 4 and the bottom 5 of the case 2.

Other configurations are possible, the protection module being for example arranged outside the case, against a wall corresponding to the position of the battery inside the case. In the case of a watch, the module is disposed between the bottom of the case and the skin of the wearer of the watch. Thus, the wearer of the watch is protected by the module in the event of runaway.

In another configuration, the protection module may be disposed against the battery, opposite to the skin of the user for bulk-related reasons. The heat flow is then diverted in the direction opposite to that of the user, thereby limiting the temperature at contact with the skin.

The module may also be arranged on an already existing electronic device, for example a mobile phone. The module is fastened on the outer face of the case corresponding to the position of the battery inside the case. Different kinds of fastening means are possible to attach the module on the face of the case, such as screws, a glue withstanding high temperatures, or magnets.

The endothermic protection module 10 is configured to be automatically triggered starting from a threshold temperature, in order to absorb at least part of the heat released by the battery.

To this end, the module 10 comprises two products 7, 8, which are separate before triggering of the module 10, and which are mixed when it is triggered. Mixing of the two products 7, 8 causes an endothermic chemical reaction, which allows absorbing heat released by the battery 4.

The products 7, 8 automatically mix together starting from a predetermined temperature serving as a threshold value. Preferably, the triggering temperature is beyond 80° C., and possibly beyond 100° C.

There are different types of products 7, 8 that could be mixed to obtain an endothermic reaction. This endothermic reaction allows absorbing at least part of the heat released by the battery. Even though the energy is absorbed only in part, the temperature of the bottom 5 of the case 2 decreases, so that the wearer of the watch avoids a burn, and feels no intense warm sensation.

To obtain an endothermic reaction, the first product 7 is for example ammonium nitrate and the second product 8 is water. Mixing of the two products 7, 8 causes an endothermic reaction.

Other pairs of products 7, 8 are possible, the first 7 and second 8 products to be mixed being selected from among the following pairs:
potassium chloride and water,
sodium carbonate and ethanoic acid,
thionyl chloride and cobalt sulphate heptahydrate,
Barium hydroxide octohydrate crystals and dry ammonium chloride.

Mixing of the products 7, 8 of each pair produces an endothermic reaction, which absorbs heat released by the battery.

In FIG. 2, the two products 7, 8 are arranged within an enclosure 6 disposed in the housing 14. The two products 7, 8 are separated by a wall 9 configured to avoid mixing of the products 7, 8. For example, it may be sealed.

The wall 9 is degradable starting from a predetermined temperature. Thus, in the event of runaway of the temperature of the battery 4, the module 10 is automatically triggered, when the temperature released by the battery 4 exceeds the threshold value.

The wall 9 is a membrane which falls apart beyond said determined temperature. For example, the membrane is a metal alloy with a low melting point, such as a MCP96®-type Bismuth alloy which has a melting point of 100° C. The melting point serves as a threshold value. Beyond the melting point, the bottom membrane and the two products could mix together.

Other alloys are possible, such as an indium-Titanium nitride eutectic alloy, a Rose metal type Lead-Bismuth-tin alloy, a Lead-Bismuth alloy, a Bismuth-Titanium nitride eutectic alloy, a Bismuth-Indium eutectic alloy.

These alloys have a different melting point, 117° C. for the indium-Titanium nitride eutectic alloy, 95° C. for the Rose metal type Lead-Bismuth-tin alloy, 125° C. for the Lead-Bismuth alloy, 138° C. for the Bismuth-Titanium nitride eutectic alloy, 109° C. for the Bismuth-Indium eutectic alloy.

Thus, depending on the desired protection, an alloy having a specific melting point is selected.

In FIG. 3, the wall has fallen apart, so that the two products 7, 8 mix together to produce the endothermic reaction.

The wall 9 may also comprise, preferably in its entirety, a polymer material, for example ABS-type acrylonitrile butadiene styrene, LDPE-type low-density polyethylene, or PVC-type polyvinyl chloride. The acrylonitrile butadiene styrene has a melting point of 130° C., the low-density polyethylene and the polyvinyl chloride having a melting point of 100° C.

In a variant of the module 20, represented in FIG. 4, the enclosure 13 includes a plurality of compartments 11, 12, each compartment 11, 12 including one of the two products 7, 8. The compartments 11, 12 have a smaller size than in the first embodiment. Preferably, the compartments 11, 12 alternatively comprise each product 7, 8.

Each compartment 11, 12 is closed by a wall 9 which is degradable at a predefined temperature. The walls 9 are of the same type as that of the first variant.

Thus, beyond the temperature threshold value, the walls of each compartment degrade, so that the two products could mix together. Thanks to this configuration, mixing of the products is done better. The module according to this embodiment is more effective, because the reaction between the products is very quick.

Of course, the present invention is not limited to the illustrated examples, but it could be subject to various variants and modifications that should appear to a person skilled in the art. Other applications are possible, beyond watchmaking, such as mobile phones, laptops, or any other mobile electronic object.

1. An electronic device, comprising a case and an electronic system arranged within the case, the case being provided with a housing for a battery allowing supplying the electronic system with energy, wherein said electronic device comprises a standalone endothermic protection module configured to be automatically triggered in the event of thermal runaway of the battery in order to absorb heat.

2. The electronic device according to claim 1, wherein the module is automatically triggered starting from a threshold temperature.

3. The electronic device according to claim 2, wherein the protection module comprises two products that are separate before triggering, and which mix together after the automatic triggering.

4. The electronic device according to claim 3, wherein the two products are arranged within an enclosure disposed in the case.

5. The electronic device according to claim 3, wherein the two products are separated by a wall before triggering, the wall being degradable beyond the threshold temperature.

6. The electronic device according to claim 5, wherein the enclosure includes a plurality of compartments, each compartment including one of the two products.

7. The electronic device according to claim 6, wherein the compartments alternatively comprise each product.

8. The electronic device according to claim 6, wherein the compartments are closed by a wall degradable beyond the threshold temperature.

9. The electronic device according to claim 4, wherein the wall comprises, a metal alloy with a low melting point.

10. The electronic device according to claim 9, wherein the wall comprises, a material to be selected from the following list: an indium-Titanium nitride eutectic alloy, a Rose metal type Lead-Bismuth-tin alloy, a Lead-Bismuth alloy, a Bismuth-Titanium nitride eutectic alloy, a Bismuth-Indium eutectic alloy.

11. The electronic device according to claim 8, wherein the wall comprises, a polymer material, for example ABS-type acrylonitrile butadiene styrene, LDPE-type low-density polyethylene, or PVC-type polyvinyl chloride.

12. The electronic device according to claim 3, wherein the first and second products to be mixed are selected from among the following pairs:
ammonium nitrate and water,
potassium chloride and water,
sodium carbonate and ethanoic acid,
thionyl chloride and cobalt sulphate heptahydrate,
Barium hydroxide octohydrate crystals and dry ammonium chloride.

13. The electronic device according to claim 1, wherein the endothermic protection module is arranged within the case.

14. The electronic device according to claim 1, wherein the endothermic protection module is arranged outside the case.
